(19) United States
(12) Patent Application Publication
(10) Pub. No.: US 2013/0130420 A1
(43) Pub. Date: May 23, 2013

(54) METHOD OF LASER LIFT-OFF FOR LEDS

(71) Applicants: Fu-Bang CHEN, Taichung City (TW); Ruei-Sian Zeng, Taichung City (TW); Chih-Sung Chang, Taichung City (TW)

(72) Inventors: Fu-Bang CHEN, Taichung City (TW); Ruei-Sian Zeng, Taichung City (TW); Chih-Sung Chang, Taichung City (TW)

(21) Appl. No.: 13/299,091

(22) Filed: Nov. 17, 2011

(51) Int. Cl. H01L 33/08

(52) U.S. Cl. 438/33; 257/E33.055

(57) ABSTRACT

A laser lift-off method for LEDs forms an elevation difference structure on a conversion substrate corresponding to one isolation zone of an epitaxial layer before epitaxy is formed on the conversion substrate to form the epitaxial layer. The elevation difference structure can release stress between the material interfaces, thus can reduce broken probability while lifting off the conversion substrate and epitaxial layer via laser and further improve production yield.

### FIELD OF THE INVENTION

The present invention relates to a method for manufacturing light emitting diodes (LEDs) and particularly to a method of laser lift-off for LEDs.

### BACKGROUND OF THE INVENTION

LED is mainly fabricated via semiconductor material formed in multiple layers of epitaxy. Take a blue light LED as an example, it mainly includes a GaN-based epitaxy film with an internal PN structure to provide one-way electric conductivity.

It is generally manufactured via a sapphire substrate to grow a GaN-based epitaxy film of a higher quality. However, the conventional sapphire substrate does not have desired electric and heat conductivity. Hence the conventional blue light LED is limited in a transverse structure for positive and negative electrodes on the same side of the substrate. Such a structure reduces light emitting area of elements. Moreover, a current crowding effect also is generated to increase conductivity resistance and forward voltage drop of the elements.

To remedy the aforesaid disadvantages, at present a high power LED element adopts a technique that grows a GaN-based epitaxy film on a sapphire substrate, then forms a new substrate on the GaN-based epitaxy film by growing a metal film thereon via plating or wafer bonding, and uses LED laser lift-off to remove the sapphire substrate so that the GaN-epitaxy film finally is planted on the new substrate. The new substrate provides a greater cooling coefficient and improved electric conductivity, thus is more suitable to be used in high driving currents, thus can resolve the cooling problem of LED elements in a high luminous flux conditions.

Please refer to FIGS. 1 and 2 for a conventional LED with removal of a sapphire substrate via a laser lift-off method. First, an epitaxial layer 2 for emitting light is formed on a conversion substrate 1 (such as a sapphire substrate) with isolation zones 3 formed to separate the epitaxial layer 2 to form dice 4; next, the epitaxial layer 2 is bonded to a support substrate 6 with a bonding metal layer 5; then a photo mask with hollow-out zones (not shown in the drawings) is provided near the conversion substrate 1, and laser 7 is also provided to transmit through the hollow-out zones to project onto the conversion substrate 1 to allow a projecting zone 8 of the laser 7 to cover the dice 4 of the epitaxial layer 2 on the conversion substrate 1 corresponding to the hollow-out zones and the isolation zones 3 surrounding the dice 4 (referring to FIG. 2).

The conventional technique uses the laser 7 to scan the entire conversion substrate 1 in a carpet manner. When the epitaxial layer 2 that is mainly made of GaN-based material is projected by the laser 7, the GaN-based material is dissociated on the interface between the conversion substrate 1 and epitaxial layer 2 to generate nitrogen gas to lift off the epitaxial layer 2 from the conversion substrate 1.

However, when the epitaxial layer 2 is formed on the conversion substrate 1, multiple fabrication processes cause a great amount of residual surface stress remaining on the material interface between the conversion substrate 1 and epitaxial layer 2. During the laser lift-off process, the nitrogen gas being generated produces a pressure to interact with the surface stress to create an unpredictable destructive force which could cause fractures on the epitaxial layer 2 in unpredictable directions, namely broken problem could take place to lower production yield.

U.S. Pat. No. 6,617,261 entitled “Structure and method for fabricating GaN substrates from trench patterned GaN layers on sapphire substrates” discloses a structure and method to fabricate a trench on an isolation zone between epitaxial layers with the trench serving as a channel to release the pressure of nitrogen gas. The trench has to be formed at a greater depth. Hence fabrication process is complex and difficult, and the cost is higher. It cannot fully meet use requirements.

### SUMMARY OF THE INVENTION

The primary object of the present invention is to solve the problem caused in a laser lift-off fabrication process that generates nitrogen gas pressure to interact with the residual surface stress to result in a destructive force which could damage the epitaxial layer, thereby to increase production yield.

The invention provides a laser lift-off method for LEDs. The method employs laser to lift off a conversion substrate and an epitaxial layer. The epitaxial layer has a plurality of isolation zones to separate the epitaxial layer to form a plurality of dice. Before epitaxy is formed on the conversion substrate to form the epitaxial layer, an elevation difference structure is formed on the conversion substrate corresponding to one isolation zone of the epitaxial layer. Then the epitaxy is grown on the conversion substrate to form the epitaxial layer.

By means of the aforesaid technique, the invention provides an advantage of releasing the stress on the material interface through the elevation difference structure. As the epitaxial layer is formed by growing epitaxy on the conversion substrate with the elevation difference structure, broken probability can be reduced while lifting off the conversion substrate and epitaxial layer via laser, thus production yield increases.

The foregoing, as well as additional objects, features and advantages of the invention will be more readily apparent from the following detailed description, which proceeds with reference to the accompanying embodiment and drawings. The embodiment merely serves for illustrative purpose and is not the limitation of the invention.

### BRIEF DESCRIPTION OF THE DRAWINGS

FIG. 1 is a schematic view of a conventional laser lift-off method for LEDs.

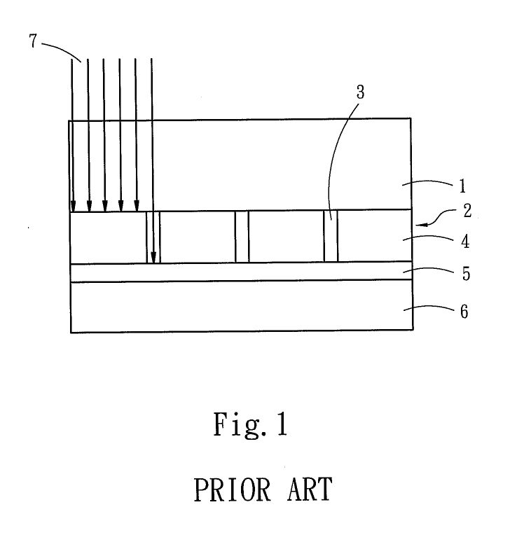

FIG. 2 is a top view of a conventional epitaxial layer.

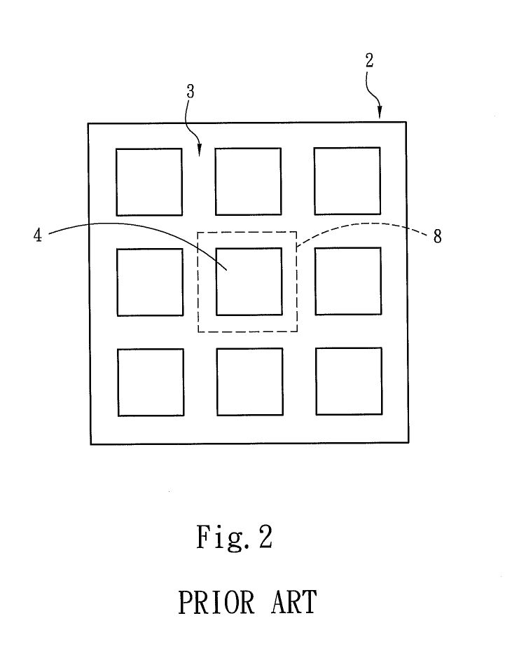

FIG. 3A is a schematic view of LED laser lift-off structure-1 according to the invention.

FIG. 3B is a schematic view of LED laser lift-off structure-2 according to the invention.

FIG. 3C is a schematic view of LED laser lift-off structure-3 according to the invention.

FIG. 3D is a schematic view of LED laser lift-off structure-4 according to the invention.

### DETAILED DESCRIPTION OF THE PREFERRED EMBODIMENT

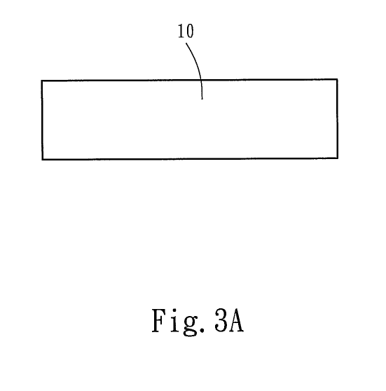

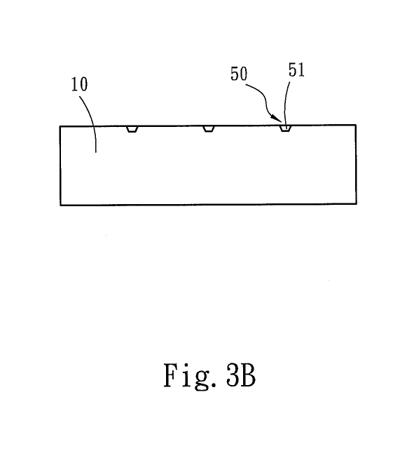

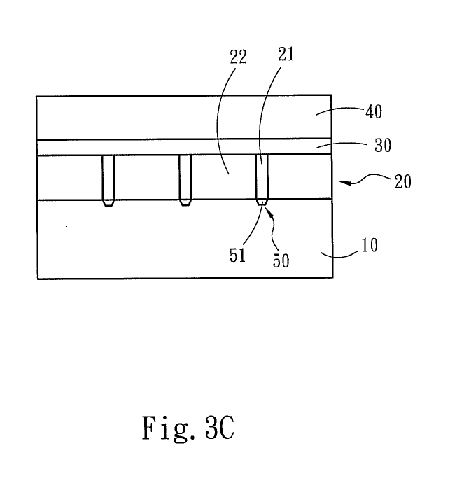

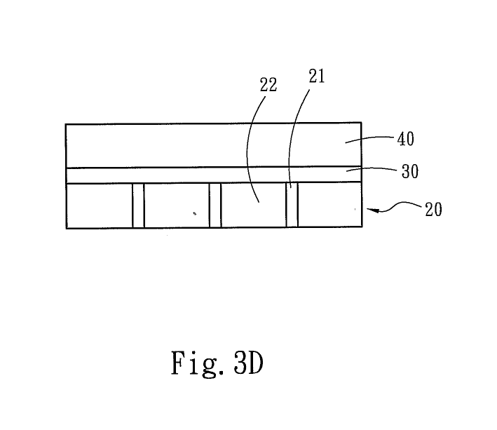

Please refer to FIGS. 3A through 3D, the present invention provides a laser lift-off method for LEDs. The method includes steps of: first, preparing a conversion substrate 10 (as shown in FIG. 3A), and forming an elevation difference structure 50 on the conversion substrate 10 (as shown in FIG. 3B); next, growing epitaxy to form an epitaxial layer 20, and bonding the epitaxial layer 20 to a support substrate 40 via a bonding metal layer 30 (as shown in FIG. 3C); and finally lifting off the conversion substrate 10 and the epitaxial layer 20 via laser (as shown in FIG. 3D).

Take a blue LED as an example. The conversion substrate 10 can be a sapphire substrate, the epitaxial layer 20 can be a GaN-based epitaxial film, and the support substrate 40 can be made of silicon, aluminum, copper, silver, silicon carbide, diamond, graphite, molybdenum, aluminum nitride or the like.

In practice, the epitaxial layer 20 includes a plurality of isolation zones 21 to separate the epitaxial layer 20 to form a plurality of dice 22. The invention employs a technique to resolve the problems in the conventional techniques by forming the elevation difference structure 50 (referring to FIG. 3B) on the conversion substrate 10 corresponding to one isolation zone 21 of the epitaxial layer 20 before the epitaxy is formed on the conversion substrate 10 to form the epitaxial layer 20. The elevation difference structure 50 can be a trench 51 which is formed in a shape of an inverse trapezium at a depth ranged from 0.1 nm to 25 nm.

After the elevation difference structure 50 has been formed on the conversion substrate 10, epitaxy is then formed on the conversion substrate 10 to form the epitaxial layer 20. Through the elevation difference structure 50, the surface stress on the material interface between the conversion substrate 10 and epitaxial layer 20 can be released. To increase the surface stress releasing effect, the elevation difference structure 50 has a cross section formed at an angle between 45 and 90 degrees.

The elevation difference structure 50 can be formed in various semiconductor manufacturing processes, such as via diamond cutting, laser cutting, semiconductor dry etching process, semiconductor wet etching process, or any other semiconductor manufacturing process capable of forming the similar structure.

In short, the invention aims to form the elevation difference structure 50 on the conversion substrate 10 corresponding to one isolation zone 21 of the epitaxial layer 20 before epitaxy is formed on the conversion substrate 10 to form the epitaxial layer 20, hence can release the stress on the material interface. Therefore, when the conversion substrate 10 and epitaxial layer 20 are lifted off via laser, the broken probability reduces and production yield increases.

What is claimed is:

1. A laser lift-off method for light emitting diodes to lift off a conversion substrate and an epitaxial layer which includes a plurality of isolation zones separating the epitaxial layer to form a plurality of dice, comprising steps of:
forming an elevation difference structure on the conversion substrate corresponding to each of the plurality of isolation zones of the epitaxial layer; and
growing epitaxy on the conversion substrate to form the epitaxial layer.

2. The laser lift-off method of claim 1, wherein the elevation difference structure has a cross section formed with an angle between 45 degrees and 90 degrees.

3. The laser lift-off method of claim 1, wherein the elevation difference structure is a trench.

4. The laser lift-off method of claim 3, wherein the trench is an inverse trapezium.

5. The laser lift-off method of claim 3, wherein the trench has a depth ranged from 0.1 nm to 25 nm.

6. The laser lift-off method of claim 1, wherein the elevation difference structure is formed by diamond cutting.

7. The laser lift-off method of claim 1, wherein the elevation difference structure is formed by laser cutting.

8. The laser lift-off method of claim 1, wherein the elevation difference structure is formed via a semiconductor dry etching process.

9. The laser lift-off method of claim 1, wherein the elevation difference structure is formed via a semiconductor wet etching process.
